(19) United States
(12) Patent Application Publication
(10) Pub. No.: US 2026/0150476 A1
(43) Pub. Date: May 28, 2026

(54) DISPLAY APPARATUS

(71) Applicant: AUO Corporation, Hsinchu City (TW)

(72) Inventors: Yen Ching Tsai, Hsinchu City (TW); Cheng-Chih Hsieh, Hsinchu City (TW)

(73) Assignee: AUO Corporation, Hsinchu City (TW)

(21) Appl. No.: 19/245,430

(22) Filed: Jun. 23, 2025

(30) Foreign Application Priority Data
Nov. 26, 2024 (TW) 113145515

(51) Int. Cl. H10H 29/80; H10H 29/37; H10H 29/49; H10H 29/851

(52) U.S. Cl. CPC H10H 29/882; H10H 29/37; H10H 29/49; H10H 29/851

(57) ABSTRACT

A display apparatus includes pixel units. Each of the pixel unit includes a bank layer, a first light-emitting element, a second light-emitting element, a third light-emitting element, a first color conversion structure, a first scattering structure, and a second scattering structure. Openings of the bank layer are arranged in multiple rows and columns along a row direction and a column direction. The first, second, and third light-emitting elements are respectively located in the first, second, and third openings of the bank layer. The first color conversion structure is disposed in the first opening. The first scattering structure is disposed in the second opening. The second scattering structure is disposed in the third opening. The first color conversion structure and the first scattering structure are arranged in a first direction. The first scattering structure and the second scattering structure are arranged in a second direction. The first direction, the second direction, the row direction, and the column direction are intersected with each other.

### CROSS-REFERENCE TO RELATED APPLICATION

This application claims the priority benefit of Taiwan application serial no. 113145515, filed on Nov. 26, 2024. The entirety of the above-mentioned patent application is hereby incorporated by reference herein and made a part of this specification.

### BACKGROUND

### Technical Field

The disclosure relates to a display apparatus.

### Description of Related Art

A light-emitting diode display panel includes a driving circuit substrate and multiple light-emitting diode elements transferred onto the driving circuit substrate. Inheriting characteristics of the light-emitting diode, the light-emitting diode display panel has advantages such as power saving, high efficiency, high brightness, and fast response time. In addition, compared to an organic light-emitting diode display panel, the light-emitting diode display panel also has advantages such as easy color adjustment, long light-emitting life, and no image burn-in. Therefore, the light-emitting diode display panel is regarded as a next-generation display technology. In the light-emitting diode display panel in a current architecture, the light-emitting diode elements are covered with a color conversion structure and a scattering structure, so that optical properties of sub-pixels which are used to emit various colors are close to each other. However, when a scattering material layer is patterned to form multiple scattering structures, a portion of the scattering material layer is likely to remain in the scattering structures, causing a height of a film surface of a subsequently formed bank layer to be uneven, affecting optical performance of the light emitting diode display panel.

### SUMMARY

The disclosure provides a display apparatus with good optical performance.

A display apparatus in the disclosure includes a driving circuit substrate and multiple pixel units. Each of the pixel units includes a bank layer, a first light-emitting element, a second light-emitting element, a third light-emitting element, a first color conversion structure, a first scattering structure, and a second scattering structure. The bank layer is disposed on the driving circuit substrate and has multiple openings. The openings of the bank layer are arranged in multiple rows and multiple columns along a row direction and a column direction. The openings of the bank layer include a first opening, a second opening, and a third opening. The first light-emitting element, the second light-emitting element, and the third light-emitting element are disposed on the driving circuit substrate, electrically connected to the driving circuit substrate, and respectively located in the first opening, the second opening, and the third opening of the bank layer. The first color conversion structure is disposed in the first opening of the bank layer and covers the first light-emitting element. The first scattering structure is disposed in the second opening of the bank layer and covers the second light-emitting element. The second scattering structure is disposed in the third opening of the bank layer and covers the third light-emitting element. The first color conversion structure and the first scattering structure respectively covering the first light-emitting element and the second light-emitting element are arranged in a first direction. The first direction is intersected with the row direction and the column direction. The first scattering structure and the second scattering structure respectively covering the second light-emitting element and the third light-emitting element are arranged in a second direction. The second direction is intersected with the row direction and the column direction, and the first direction is intersected with the second direction.

### BRIEF DESCRIPTION OF THE DRAWINGS

FIG. 1 is a schematic top perspective view of a display apparatus according to an embodiment of the disclosure.

FIG. 2 is a schematic cross-sectional view of a display apparatus according to an embodiment of the disclosure.

FIG. 3 is a schematic cross-sectional view of a display apparatus according to an embodiment of the disclosure.

FIG. 4 is a schematic view of an equivalent circuit of a display apparatus according to an embodiment of the disclosure.

FIG. 5 is a schematic top perspective view of a display apparatus according to another embodiment of the disclosure.

### DETAILED DESCRIPTION OF DISCLOSED EMBODIMENTS

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

It should be understood that when an element such as a layer, film, region, or substrate is referred to as being “on” or “connected to” another element, it may be directly on or connected to another element, or there may be an intervening element or layer therebetween. In contrast, when an element is referred to as being “directly on” or “directly connected to” another element, no intervening element exists therebetween. As used herein, the term “connected” may refer to physically connected and/or electrically connected. Furthermore, “electrical connection” or “coupling” may mean that there are other elements between two elements.

The term “about”, “approximately”, or “substantially” used herein includes the value and an average value within an acceptable deviation range of specific values determined by a person of ordinary skill in the art, taking into account discussed measurements and a specific number of measurement-related errors (i.e., limitations of a measuring system). For example, the term “about” may mean being within one or more standard deviations of the value, or within, for example, ±30%, ±20%, ±10%, and ±5%. Moreover, the term “about”, “approximately”, or “substantially” used herein may mean selecting a more acceptable deviation range or standard deviations according to optical properties, etching properties, or other properties, without applying a single standard deviation to all properties.

Unless otherwise defined, all terminologies (including technical and scientific terminologies) used herein have the same meaning as commonly understood by people having ordinary skill in the art to which the disclosure belongs. It is understood that these terminologies, such as those defined in commonly used dictionaries, should be interpreted as having meanings consistent with the relevant art and the background or context of the disclosure, and should not be interpreted in an idealized or overly formal way, unless otherwise defined in the embodiments of the disclosure.

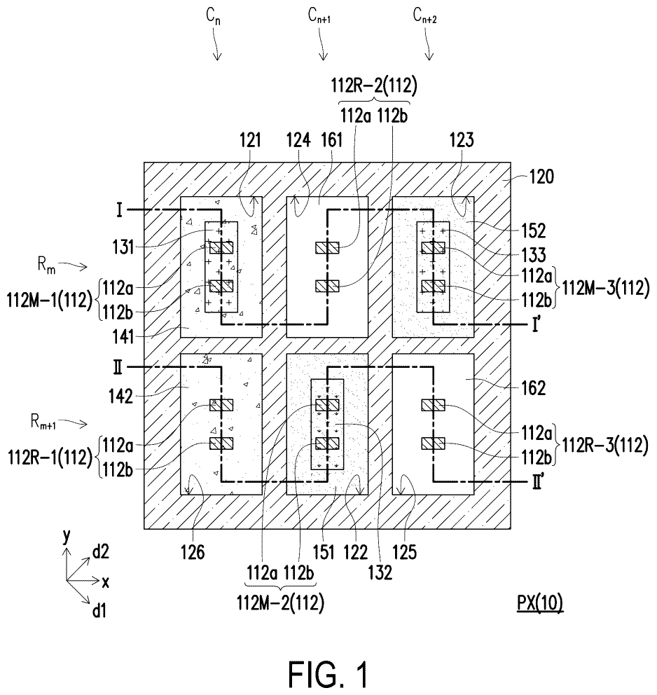

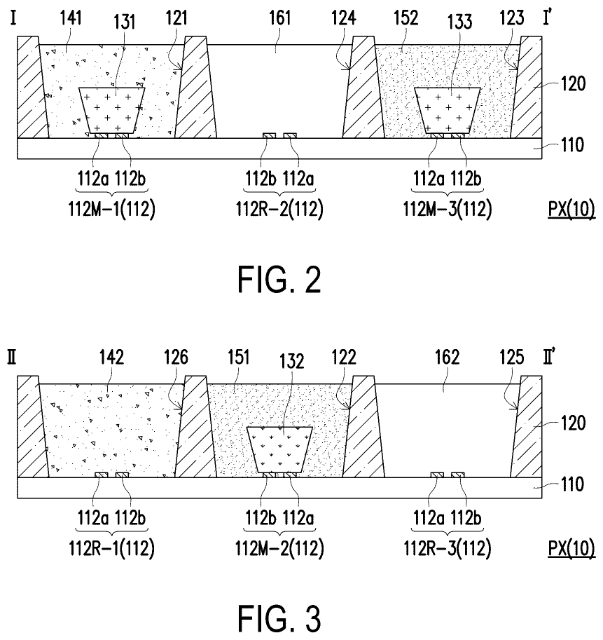

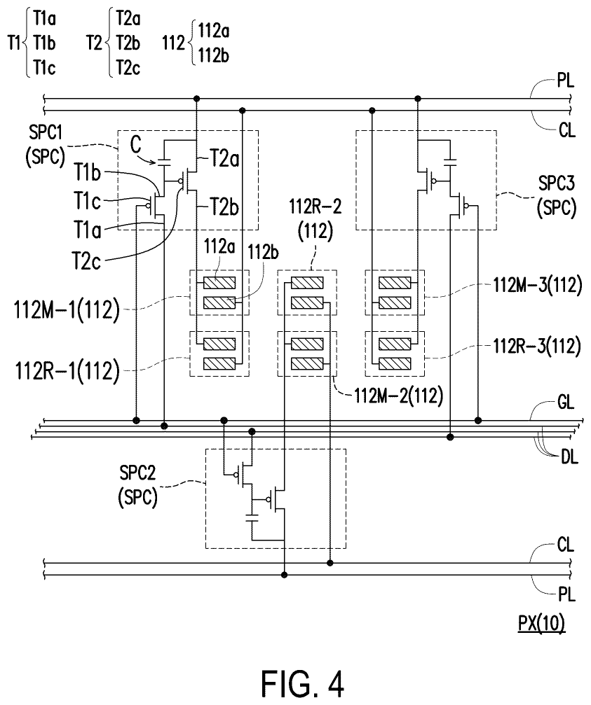

FIG. 1 is a schematic top perspective view of a display apparatus according to an embodiment of the disclosure. FIG. 2 is a schematic cross-sectional view of a display apparatus according to an embodiment of the disclosure. FIG. 2 corresponds to a section line I-I′ in FIG. 1. FIG. 3 is a schematic cross-sectional view of a display apparatus according to an embodiment of the disclosure. FIG. 3 corresponds to a section line II-II′ in FIG. 1. FIG. 4 is a schematic view of an equivalent circuit of a display apparatus according to an embodiment of the disclosure. FIGS. 1, 2, 3, and 4 illustrate one pixel unit PX of a display apparatus 10 as an example. Those skilled in the art should be able to implement the entire display apparatus 10 according to FIGS. 1, 2, 3, and 4 and the following description, and multiple pixel units PX will not be repeatedly illustrated here.

Referring to FIGS. 1, 2, 3, and 4, the display apparatus 10 includes a driving circuit substrate 110. The driving circuit substrate 110 includes multiple subpixel driving circuits SPC (shown in FIG. 4) and multiple pad groups 112 electrically connected to the subpixel driving circuits SPC. Each of the pad groups 112 includes at least one pad 112a and 112b.

Referring to FIG. 4, for example, in some embodiments, each of the subpixel driving circuits SPC may include a first transistor T1, a second transistor T2, and a capacitor C. A first end T1a of the first transistor T1 is electrically connected to one corresponding data line DL. A control end T1c of the first transistor T1 is electrically connected to one corresponding scan line GL. A second end T1b of the first transistor T1 is electrically connected to a control end T2c of the second transistor T2. A first end T2a of the second transistor T2 is electrically connected to one corresponding power line PL. The capacitor C is electrically connected to the second end T1b of the first transistor T1 and the first end T2a of the second transistor T2. A second end T2b of the second transistor T2 is electrically connected to one corresponding pad group 112. Referring to FIGS. 1 and 4, in some embodiments, each of the pad groups 112 may selectively include multiple pads 112a and 112b. One pad 112a may be electrically connected to one corresponding subpixel driving circuit SPC, and the other pad 112b may be electrically connected to one corresponding shared line CL. However, the disclosure is not limited thereto, and in other embodiments, each of the pad groups 112 may also include only one pad 112a.

Referring to FIGS. 1, 2, and 3, the display apparatus 10 further includes the pixel units PX. Each of the pixel units PX includes a bank layer 120 disposed on the driving circuit substrate 110 and having multiple openings 121, 122, 123, 124, 125, and 126. Referring to FIG. 1, the openings 121, 122, 123, 124, 125, and 126 of the bank layer 120 are arranged in multiple rows Cₙ, Cₙ₊₁, and Cₙ₊₂ and multiple columns Rₘ and Rₘ₊₁ along a row direction y and a column direction x. The row direction y is intersected with the column direction x. For example, in some embodiments, the row direction y and the column direction x may be substantially perpendicular, but the disclosure is not limited thereto.

Referring to FIG. 1, in some embodiments, the openings 121, 122, 123, 124, 125, and 126 of the bank layer 120 of each of the pixel units PX may include the first opening 121, the second opening 122, the third opening 123, the fourth opening 124, the fifth opening 125, and the sixth opening 126. The first opening 121, the fourth opening 124, and the third opening 123 are located in the column Rₘ. The sixth opening 126, the second opening 122, and the fifth opening 125 are located in the next column Rₘ₊₁. The first opening 121 and the sixth opening 126 are located in the row Cₙ. The fourth opening 124 and the second opening 122 are located in the next row Cₙ₊₁. The third opening 123 and the fifth opening 125 are located in the further next row Cₙ₊₂.

The first opening 121, the fourth opening 124, and the third opening 123 are arranged in the column direction x, and the fourth opening 124 is located between the first opening 121 and the third opening 123. The sixth opening 126, the second opening 122, and the fifth opening 125 are arranged in the column direction x, and the second opening 122 is located between the sixth opening 126 and the fifth opening 125. The sixth opening 126 and the first opening 121 are arranged in the row direction y. The second opening 122 and the fourth opening 124 are arranged in the row direction y. The fifth opening 125 and the third opening 123 are arranged in the row direction y. In some embodiments, a material of the bank layer 120 may selectively be reflective, but the disclosure is not limited thereto. In some embodiments, a color of the bank layer 120 may selectively be white, but the disclosure is not limited thereto.

Referring to FIGS. 1 and 4, in some embodiments, the pad groups 112 located in the openings 121, 122, 123, 124, 125, and 126 of the same pixel unit PX are electrically connected to the subpixel driving circuits SPC, and the subpixel driving circuits SPC are electrically connected to the same scan line GL.

Referring to FIGS. 1 and 4, in some embodiments, the pad groups 112 of the driving circuit substrate 110 may include multiple main pad groups 112M-1, 112M-2, and 112M-3 and multiple spare pad groups 112R-1, 112R-2, and 112R-3. Each of the spare pad groups 112R-1/112R-2/112R-3 is electrically connected to one corresponding main pad group 112M-1/112M-2/112M-3. For example, in some embodiments, the main pad group 112M-1 and the spare pad group 112R-1 respectively located in the first opening 121 and the sixth opening 126 are electrically connected to each other, the spare pad group 112R-2 and the main pad group 112M-2 respectively located in the fourth opening 124 and the second opening 122 are electrically connected to each other, and the main pad group 112M-3 and the spare pad group 112R-3 respectively located in the third opening 123 and the fifth opening 125 are electrically connected to each other.

In detail, in some embodiments, the subpixel driving circuits SPC include a first subpixel driving circuit SPC1, a second subpixel driving circuit SPC2, and a third subpixel driving circuit SPC3. One pad 112a of the main pad group 112M-1 located in the first opening 121 and one pad 112a of the spare pad group 112R-1 located in the sixth opening 126 are both electrically connected to the first subpixel driving circuit SPC1, and the other pad 112b of the main pad group 112M-1 located in the first opening 121 and the other pad 112b of the spare pad group 112R-1 located in the sixth opening 126 are electrically connected to the same shared line CL. One pad 112a of the spare pad group 112R-2 located in the fourth opening 124 and one pad 112a of the main pad group 112M-2 located in the second opening 122 are both electrically connected to the second subpixel driving circuit SPC2, and the other pad 112b of the spare pad group 112R-2 located in the fourth opening 124 and the other pad 112b of the main pad group 112M-1 located in the second opening 122 are electrically connected to the same shared line CL. One pad 112a of the main pad group 112M-3 located in the third opening 123 and one pad 112a of the spare pad group 112R-3 located in the fifth opening 125 are both electrically connected to the second subpixel driving circuit SPC2, and the other pad 112b of the main pad group 112M-3 located in the third opening 123 and the other pad 112b of the spare pad group 112R-3 located in the fifth opening 125 are electrically connected to the same shared line CL.

Referring to FIGS. 1, 2, and 3, each of the pixel units PX of the display apparatus 10 further includes a first light-emitting element 131, a second light-emitting element 132, and a third light-emitting element 133. The first light-emitting element 131, the second light-emitting element 132, and the third light-emitting element 133 are respectively located in the first opening 121, the second opening 122, and the third opening 123 of the bank layer 120. The first light-emitting element 131, the second light-emitting element 132, and the third light-emitting element 133 are disposed on the driving circuit substrate 110 and are electrically connected to the driving circuit substrate 110. In detail, in some embodiments, the first light-emitting element 131, the second light-emitting element 132, and the third light-emitting element 133 are respectively bonded to the main pad group 112M-1, the main pad group 112M-2, and the main pad group 112M-3 of the driving circuit substrate 110. For example, in some embodiments, the first light-emitting element 131 may be a micro light-emitting diode for emitting blue light, the second light-emitting element 132 may be a micro light-emitting diode for emitting green light, and the third light-emitting element 133 may be a micro light emitting diode for emitting the blue light. However, the disclosure is not limited thereto.

Referring to FIGS. 1 and 2, each of the pixel units PX of the display apparatus 10 further includes a first color conversion structure 141 disposed in the first opening 121 of the bank layer 120 and covering the first light-emitting element 131. For example, in some embodiments, the first color conversion structure 141 may convert the blue light emitted by the first light-emitting element 131 into red light, but the disclosure is not limited thereto. Referring to FIGS. 1 and 3, in some embodiments, each of the pixel units PX of the display apparatus 10 may further selectively include a second color conversion structure 142 disposed in the sixth opening 126 of the bank layer 120 and covering the spare pad group 112R-1. In some embodiments, the second color conversion structure 142 may convert the blue light into the red light, but the disclosure is not limited thereto.

Referring to FIGS. 1 and 3, each of the pixel units PX of the display apparatus 10 further includes a first scattering structure 151 disposed in the second opening 122 of the bank layer 120 and covering the second light-emitting element 132. In some embodiments, the first scattering structure 151 may include a transparent substrate and scattering particles mixed into the transparent substrate. A light beam emitted by the second light-emitting element 132 may be scattered by the first scattering structure 151, and a color of the light beam emitted by the second light-emitting element 132 is substantially not changed by the first scattering structure 151.

Referring to FIGS. 1 and 2, in some embodiments, each of the pixel units PX of the display apparatus 10 further includes a first transparent structure 161 disposed in the fourth opening 124 of the bank layer 120. The first transparent structure 161 does not include the scattering particles. In some embodiments, the first transparent structure 161 may be cured and formed by an optical glue filled in the fourth opening 124.

Referring to FIGS. 1 and 2, each of the pixel units PX of the display apparatus 10 further includes a second scattering structure 152 disposed in the third opening 123 of the bank layer 120 and covering the third light-emitting element 133. In some embodiments, the second scattering structure 152 may include the transparent substrate and the scattering particles mixed into the transparent substrate. A light beam emitted by the third light-emitting element 133 may be scattered by the second scattering structure 152, and a color of the light beam emitted by the third light-emitting element 133 is substantially not changed by the second scattering structure 152.

Referring to FIGS. 1 and 3, in some embodiments, each of the pixel units PX of the display apparatus 10 further includes a second transparent structure 162 disposed in the fifth opening 125 of the bank layer 120. The second transparent structure 162 does not include the scattering particles. In some embodiments, the second transparent structure 162 may be cured and formed by the optical glue filled in the fifth opening 125.

Referring to FIG. 1, it is worth noting that the first color conversion structure 141 and the first scattering structure 151 respectively covering the first light-emitting element 131 and the second light-emitting element 132 are arranged in a first direction d1, and the first direction d1 is intersected with the row direction y and the column direction x, the first scattering structure 151 and the second scattering structure 152 respectively covering the second light-emitting element 132 and the third light-emitting element 133 are arranged in a second direction d2, and the second direction d2 is intersected with the row direction y and the column direction x, and the first direction d1 is intersected with the second direction d2. That is, in the same pixel unit PX, the first scattering structure 151 and the second scattering structure 152 respectively covering the second light-emitting element 132 and the third light-emitting element 133 are located in different columns and different rows. Therefore, in a manufacturing process of the display apparatus 10, when a scattering material layer (not shown) is patterned to form the first scattering structure 151 and the second scattering structure 152, the scattering material layer is unlikely to remain between the first scattering structure 151 and the second scattering structure 152. As a result, the bank layer 120 formed subsequently is also unlikely to be located on the residual scattering material layer between the first scattering structure 151 and the second scattering structure 152 to affect optical performance of the display apparatus 10.

Referring to FIGS. 1 and 2, in some embodiments, the first transparent structure 161 may separate the first color conversion structure 141 and the second scattering structure 152. Referring to FIG. 1, in some embodiments, the first transparent structure 161 and the second transparent structure 162 may be arranged in the first direction d1 that is not parallel to the column direction x and the row direction y.

Referring to FIGS. 1 and 3, in some embodiments, the first scattering structure 151 and the second transparent structure 162 are arranged in the column direction x, and the first scattering structure 151 is located between the second color conversion structure 142 and the second transparent structure 162.

Referring to FIG. 1, in some embodiments, the main pad group 112M-1 and the spare pad group 112R-1 respectively overlap the first color conversion structure 141 and the second color conversion structure 142. Referring to FIG. 1, in some embodiments, the main pad group 112M-2 and the spare pad group 112R-2 respectively overlap the first scattering structure 151 and the first transparent structure 161. Referring to FIG. 1, in some embodiments, the main pad group 112M-3 and the spare pad group 112R-3 respectively overlap the second scattering structure 152 and the second transparent structure 162.

It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

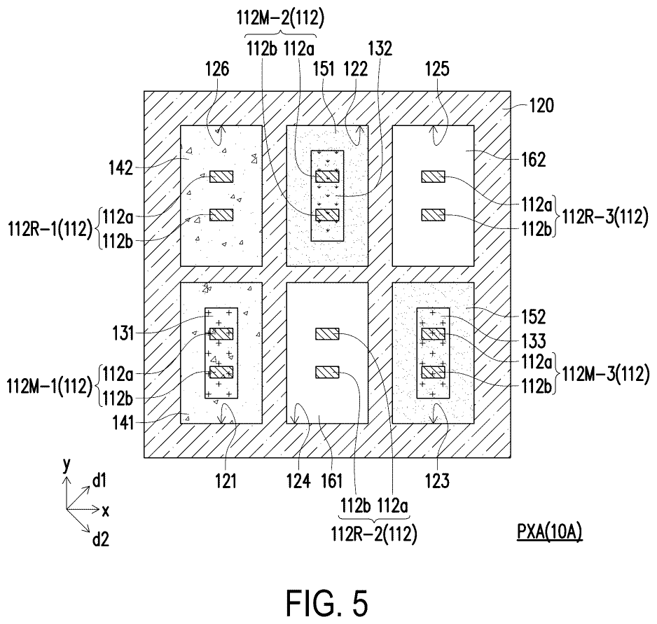

FIG. 5 is a schematic top perspective view of a display apparatus according to another embodiment of the disclosure. A display apparatus 10A in FIG. 5 is similar to the display apparatus 10 in FIG. 1, and a difference between the two is that in the embodiment of FIG. 5, the first color conversion structure 141 and the first scattering structure 151 respectively covering the first light-emitting element 131 and the second light-emitting element 132 are arranged in the first direction d1, and the first direction d1 is substantially directed from a lower left of FIG. 5 to a lower right of FIG. 5; the first scattering structure 151 and the second scattering structure 152 respectively covering the second light-emitting element 132 and the third light-emitting element 133 are arranged in the second direction d2, and the second direction d2 is directed from an upper left of FIG. 5 to the lower right of FIG. 5.

What is claimed is:

1. A display apparatus, comprising:
a driving circuit substrate; and
a plurality of pixel units, wherein each of the pixel units comprises:
a bank layer disposed on the driving circuit substrate and having a plurality of openings, wherein the openings of the bank layer are arranged in a plurality of rows and a plurality of columns along a row direction and a column direction, and the openings of the bank layer comprise a first opening, a second opening, and a third opening;
a first light-emitting element, a second light-emitting element, and a third light-emitting element disposed on the driving circuit substrate, electrically connected to the driving circuit substrate, and respectively located in the first opening, the second opening, and the third opening of the bank layer;
a first color conversion structure disposed in the first opening of the bank layer and covering the first light-emitting element;
a first scattering structure disposed in the second opening of the bank layer and covering the second light-emitting element; and
a second scattering structure disposed in the third opening of the bank layer and covering the third light-emitting element;
wherein the first color conversion structure and the first scattering structure respectively covering the first light-emitting element and the second light-emitting element are arranged in a first direction, the first direction is intersected with the row direction and the column direction, the first scattering structure and the second scattering structure respectively covering the second light-emitting element and the third light-emitting element are arranged in a second direction, the second direction is intersected with the row direction and the column direction, and the first direction is intersected with the second direction.

2. The display apparatus according to claim 1, wherein the openings of the bank layer further comprise a fourth opening, the first opening, the fourth opening, and the third opening of the bank layer are arranged in the column direction, the fourth opening is located between the first opening and the third opening, and the display apparatus further comprises:
a first transparent structure disposed in the fourth opening of the bank layer;
wherein the first transparent structure separates the first color conversion structure and the second scattering structure.

3. The display apparatus according to claim 2, wherein the openings of the bank layer further comprise a fifth opening, the third opening and the fifth opening of the bank layer are arranged in the row direction, and the display apparatus further comprises:
a second transparent structure disposed in the fifth opening of the bank layer;
wherein the first transparent structure and the second transparent structure are arranged in the first direction.

4. The display apparatus according to claim 3, wherein the openings of the bank layer further comprise a sixth opening, the first opening and the sixth opening of the bank layer are arranged in the row direction, the sixth opening and the second opening of the bank layer are arranged in the column direction, and the display apparatus further comprises:
a second color conversion structure disposed in the sixth opening of the bank layer.

5. The display apparatus according to claim 4, wherein the second color conversion structure, the first scattering structure, and the second transparent structure are arranged in the column direction, and the first scattering structure is located between the second color conversion structure and the second transparent structure.

6. The display apparatus according to claim 3, wherein the driving circuit substrate has a main pad group and a spare pad group electrically connected to each other, the second light-emitting element is bonded to the main pad group, and the main pad group and the spare pad group respectively overlap the first scattering structure and the first transparent structure.

7. The display apparatus according to claim 3, wherein the driving circuit substrate has a main pad group and a spare pad group electrically connected to each other, the third light-emitting element is bonded to the main pad group, and the main pad group and the spare pad group respectively overlap the second scattering structure and the second transparent structure.

8. A display apparatus, comprising:
a driving circuit substrate; and
a plurality of pixel units, wherein each of the pixel units comprises:
a bank layer disposed on the driving circuit substrate and having a plurality of openings, wherein the openings of the bank layer are arranged in a plurality of rows and a plurality of columns along a row direction and a column direction, and the openings of the bank layer comprise a first opening, a second opening, and a third opening;
a first light-emitting element, a second light-emitting element, and a third light-emitting element disposed on the driving circuit substrate, electrically connected to the driving circuit substrate, and respectively located in the first opening, the second opening, and the third opening of the bank layer;
a first color conversion structure disposed in the first opening of the bank layer and covering the first light-emitting element;
a first scattering structure disposed in the second opening of the bank layer and covering the second light-emitting element; and
a second scattering structure disposed in the third opening of the bank layer and covering the third light-emitting element;
wherein the first color conversion structure and the first scattering structure respectively covering the first light-emitting element and the second light-emitting element are arranged in a first direction, the first direction is intersected with the row direction and the column direction, the first scattering structure and the second scattering structure respectively covering the second light-emitting element and the third light-emitting element are arranged in a second direction, the second direction is intersected with the row direction and the column direction, and the first direction is intersected with the second direction;
the openings of the bank layer further comprise a fourth opening, the first opening, the fourth opening, and the third opening of the bank layer are arranged in the column direction, the fourth opening is located between the first opening and the third opening, and the display apparatus further comprises a first transparent structure disposed in the fourth opening of the bank layer.

9. The display apparatus according to claim 8, wherein the openings of the bank layer further comprise a fifth opening, the third opening and the fifth opening of the bank layer are arranged in the row direction, and the display apparatus further comprises:
a second transparent structure disposed in the fifth opening of the bank layer.

10. The display apparatus according to claim 9, wherein the first transparent structure and the second transparent structure are arranged in the first direction.

11. The display apparatus according to claim 9, wherein the openings of the bank layer further comprise a sixth opening, the first opening and the sixth opening of the bank layer are arranged in the row direction, the sixth opening and the second opening of the bank layer are arranged in the column direction, and the display apparatus further comprises:
a second color conversion structure disposed in the sixth opening of the bank layer.

12. The display apparatus according to claim 11, wherein the second color conversion structure, the first scattering structure, and the second transparent structure are arranged in the column direction.

13. The display apparatus according to claim 12, wherein the first scattering structure is located between the second color conversion structure and the second transparent structure.

14. The display apparatus according to claim 9, wherein the driving circuit substrate has a main pad group and a spare pad group electrically connected to each other, the second light-emitting element is bonded to the main pad group, and the main pad group and the spare pad group respectively overlap the first scattering structure and the first transparent structure.

15. The display apparatus according to claim 9, wherein the driving circuit substrate has a main pad group and a spare pad group electrically connected to each other, the third light-emitting element is bonded to the main pad group, and the main pad group and the spare pad group respectively overlap the second scattering structure and the second transparent structure.
